(19) United States
(12) Patent Application Publication
(10) Pub. No.: US 2010/0051087 A1
(43) Pub. Date: Mar. 4, 2010

(54) FRAMELESS THIN-FILM SOLAR PHOTOVOLTAIC PANELS AND METHOD

(76) Inventors: MARVIN KESHNER, Sonora, CA (US); Don Rice, San Jose, CA (US); Philip Liu, Fremont, CA (US); Erik Vaaler, Redwood City, CA (US)

Correspondence Address: WEISS & MOY PC, 4204 NORTH BROWN AVENUE, SCOTTSDALE, AZ, 85251, US

(21) Appl. No.: 12/201,203

(22) Filed: Aug. 29, 2008

(51) Int. Cl. H01L 31/052; H01L 31/048; H01L 31/18

(52) U.S. Cl. 136/246; 136/251; 438/66; 438/73

(57) ABSTRACT

A solar panel utilizes at least one and, in one embodiment, three protective layers to eliminate the need for a metal frame. The protective layers may include one inorganic layer and two polymer layers, which are cured onto an underside of the panel. In one embodiment, the protective layers are cured over lateral edges of certain of the layers of the solar panel, including for example the conductor layers, semiconductor junction, and reflector layer. The protective layers may extend to cover an exposed edge along an underside of panel's superstrate. In one embodiment, the lateral edge of the superstrate is contoured to resist damage from rough handling and/or exposure to the elements. A support platform may be provided, and the solar panel secured thereon by way of interposing an adhesive between an underside of the panel and the support platform.

### RELATED APPLICATION

The present application relates to U.S. patent application Ser. No. 11/947,543, entitled “Conformal Protective Coating for Solar Panel.”

### FIELD OF THE INVENTION

The present invention relates to thin-film solar photovoltaic panels, modules, fabrication and assembly methods and, more particularly, to a thin-film photovoltaic solar panel without a frame around the edges that achieves the requirements normally provided by a frame.

### BACKGROUND OF THE INVENTION

Thin-film photovoltaic solar panels have been constructed with a number of substrates and/or backing materials. Current designs have used glass substrates, glass superstrates, stainless steel substrates, and plastic substrates. In one common prior art design, thin-film glass solar panels are manufactured by starting with a glass superstrate onto which are deposited a set of thin-films that create the solar cell. Sunlight enters through the front surface of the glass superstrate and is absorbed by the thin-films on the back surface and converted by them to electricity. From the sunlight side, or front of the solar panel, the thin-films are protected from the environment by the glass of the glass superstrate. From the back side of the solar panel, the thin-films are protected from the environment by a series of protective layers that are separately fabricated as sheets, and then attached to the panel over the thin-films. The sheet materials are often heavy, expensive, or both. The attachment of these sheets is an extra manufacturing step that is typically a batch process. Finally, a metal frame is added around the entire perimeter of the solar panel, to compress laminated protective layers, to protect electrical connections, to add additional mechanical strength if needed, to protect the superstrate and to provide for an attachment point for mounting the panel on a support structure.

The metal frames used in the prior art solar panels have several significant deficiencies associated therewith. First, they are expensive and add significant cost to the solar panel. Second, on the back side of the solar panel, they tend to hold water at the edges of the solar panel. This held water tends to encourage water ingress between the protective sheets and the thin-film materials of the solar panel. Third, on the sunlight-facing or front side of the solar panel, they collect water and dirt. This dirt absorbs the sunlight and reduces the amount of sunlight that is converted into electricity. Even if the dirt only collects near frame edges, the resulting power loss can be quite significant because, in many cases, the solar panels are divided into a large number of thin segments that are then connected in series. Since they are connected in series, the current of the entire solar panel is limited by the current of the segment with the smallest current. Therefore, even a thin line of dirt at the edge of the solar panel will significantly reduce the current of the segment closest to that edge—and because of the series connection between segments, the current of the entire solar panel will drop to a much greater extent than the fractional area of the panel that is actually covered by the dirt..

Fourth, the frame can wear against the superstrate when wind or thermal expansion and contraction exert repeated stress on the panel, causing micro-cracks to develop in the glass superstrate. These micro-cracks can cause a panel to fail in multiple ways; they can trap dust that blocks light from the panel, admit moisture and contaminants that can attack the functional films, propagate into the functional films and destroy their electrical integrity, or promote panel breakage in extreme conditions such as storms. Fifth, by its very design to hold the glass module tightly, the frame will collect and trap moisture as the ambient temperature and humidity change over daily and seasonal cycles. Collected water can accelerate the deterioration of the solar panels in outdoor environments. It can also accelerate the adhesive failure of the protective back layers to the solar panel. This adhesive failure of he back coats has been a major failure mode of framed solar panels.

Sixth, the frame can act as a short circuit to ground for the exposed glass surfaces that result in delamination of the thin-films due to sodium migration or an equivalent. Finally, the assembly of the frames onto the solar panel is a process that is relatively expensive to automate. Hand assembly adds additional cost, yield loss and makes the solar panel less reliable. Even when the assembly is automated, steps such as lamination are generally batch processes. Compared to continuous processes, batch processes add expense (1) through requiring a large space where a batch of large panels can be processed simultaneously, and (2) the loss of entire batches whenever the process goes wrong.

### SUMMARY OF THE INVENTION

In accordance with an embodiment of the present invention, a solar panel is disclosed. The solar panel comprises, in combination: a transparent superstrate; a first conductor disposed onto the superstrate; wherein the first conductor forms a contact for the solar panel of a first polarity; at least one device layer adapted to convert sunlight to electricity; a second conductor; wherein the second conductor forms a contact for the solar panel of a second, opposite polarity; wherein the at least one device layer is interposed between the first and second conductors; a reflector; wherein the at least one protective layer has been cured on the solar panel.

In accordance with another embodiment of the present invention, a method for fabricating a solar panel is disclosed. The method comprises: providing a transparent superstrate; disposing a first conductor onto the superstrate; wherein the first conductor forms a contact for the solar panel of a first polarity; providing at least one device layer adapted to convert sunlight to electricity; providing a second conductor; wherein the second conductor forms a contact for the solar panel of a second, opposite polarity; wherein the at least one device layer is interposed between the first and second conductors; providing a reflector located below the second conductor; curing at least one protective layer onto the solar panel below the reflector.

In accordance with yet another embodiment of the present invention, a solar panel is disclosed. The solar panel comprises, in combination: a transparent superstrate; a first conductor disposed onto the superstrate; wherein the first conductor forms a contact for the solar panel of a first polarity; at least one device layer adapted to convert sunlight to electricity; a second conductor; wherein the second conductor forms a contact for the solar panel of a second, opposite polarity; wherein the at least one device layer is interposed between the first and second conductors; a reflector; at least three protective layers located below the reflector, comprising at least one inorganic layer and at least two polymer layers; wherein the at least three protective layers have been cured on the solar panel; wherein the at least one inorganic layer comprises one of Si₃N₄ and SiO₂; wherein each of the at least two polymer layers comprises one of EVA, polyvinyl fluoride and an acrylate; wherein the at least three protective layers extend over a lateral edge of the first conductor, the second conductor, the semiconductor junction, and the reflector; and wherein adhesion of the at least three protective layers is sufficiently strong that a frame is not required around edges of the solar panel to prevent the at least three protective layers from peeling off the solar panel, beginning at the edge, during use.

In accordance with a further embodiment of the present invention, a method for converting sunlight into electricity is disclosed. The method comprises: providing a photovoltaic cell comprising, in combination: a transparent superstrate; a first conductor disposed onto the superstrate; wherein the first conductor forms a contact for the solar panel of a first polarity; at least one device layer adapted to convert sunlight to electricity; a second conductor; wherein the second conductor forms a contact for the solar panel of a second, opposite polarity; wherein the at least one device layer is interposed between the first and second conductors; a reflector; at least one protective layer located below the reflector; wherein the at least one protective layer has been r cured on the solar panel; positioning the photovoltaic cell so that sunlight may enter the glass superstrate and thereafter pass through the device layer, where a portion of the sunlight is converted into electricity; and outputting the electricity from the photovoltaic cell.

### BRIEF DESCRIPTION OF THE DRAWINGS

FIG. 1 a side, cross-sectional view of a prior art single junction amorphous silicon thin-film solar panel on a superstrate with protective back coating

FIG. 2 is a side, cross-sectional view of a single junction amorphous silicon thin-film solar panel on a superstrate with thin-film protective back coatings, consistent with an embodiment of the present invention.

FIG. 3 is a side, cross-sectional view of a single-junction thin-film solar panel on a superstrate with thin-film protective back coatings, consistent with another embodiment of the present invention.

FIG. 4(a) is a side view illustrating a contoured edge of a glass superstrate portion of a thin-film solar panel consistent with an embodiment of the present invention.

FIG. 4(b) is a side view illustrating a contoured edge of a glass superstrate portion of a thin-film solar panel consistent with another embodiment of the present invention.

FIG. 4(c) is a side view illustrating a contoured edge of a glass superstrate portion of a thin-film solar panel consistent with a further embodiment of the present invention.

FIG. 5(a) is a top view illustrating a plurality of solar panels mounted on an underlying support structure and attached to the support structure away from the edges.

FIG. 5(b) is an end view illustrating attachment of a solar panel to an underlying support structure away from the edges.

### DETAILED DESCRIPTION OF THE PREFERRED EMBODIMENTS

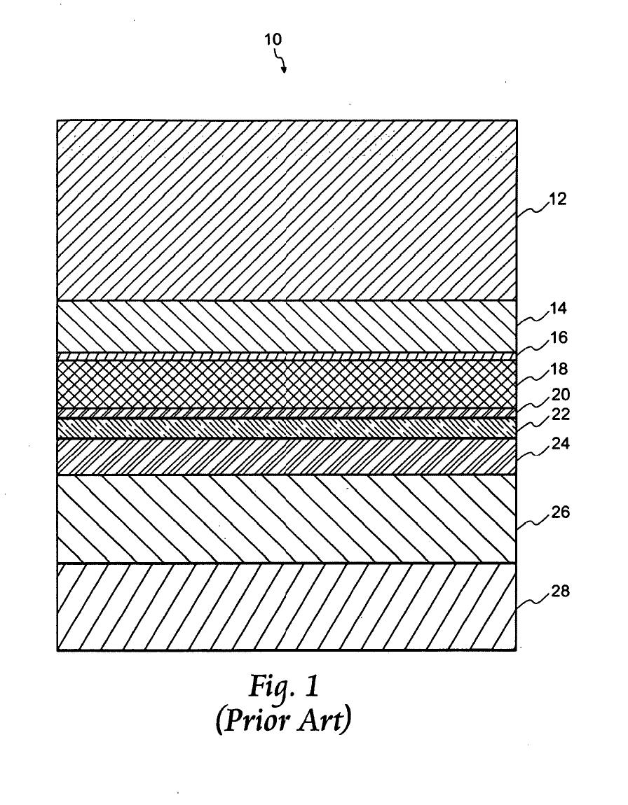

Referring first to FIG. 1, a prior art amorphous silicon, single junction, solar panel 10 is illustrated. The solar panel 10 consists of a glass superstrate 12, a first layer of transparent conductive oxide (e.g., SnO₂, ZnO, InSnO, etc.) 14, a p-layer 16, an I-layer 18 and an n-layer 20 of amorphous silicon, a second layer of transparent conductive oxide 22 and then a layer or layers of metals (e.g., aluminum, silver or silver and titanium, etc.) 24. The amorphous silicon layers 16, 18 and 20 convert the sunlight into electricity. The first conductive oxide layer 12 may be an electrical connection that becomes the positive contact. The second conductive oxide 22 plus the metal layer 24 form an electrical connection that may become the negative contact to the solar cell.

As shown in FIG. 1, a prior art solar panel 10 may further include a first protective layer 26, which may be of EVA, and a second protective layer 28, which may be a polyvinyl fluoride such as Tedlar®. In the prior art, the first and second protective layers 26 and 28 are purchased in sheet form and then laminated onto the back of the solar panel. The process of lamination of thick sheets of polymer tends to create a weak adhesion between the polymer sheet and the back of the solar panel 10. It is especially weak at the edges of the solar panel, where chips, scratches, or repeated temperature or freeze-thaw cycling can loosen the laminations at the edge of the solar panel and encourage it to peel off. In the prior art, a frame (not shown) is required around the edges of the solar panel to apply pressure to the edges of the laminations and to prevent them from de-laminating at the edges. The frame can wear the superstrate edges, resulting in micro cracks that, in turn, will initiate cracks in the panel and ultimate failure of the glass superstrate and the entire solar panel.

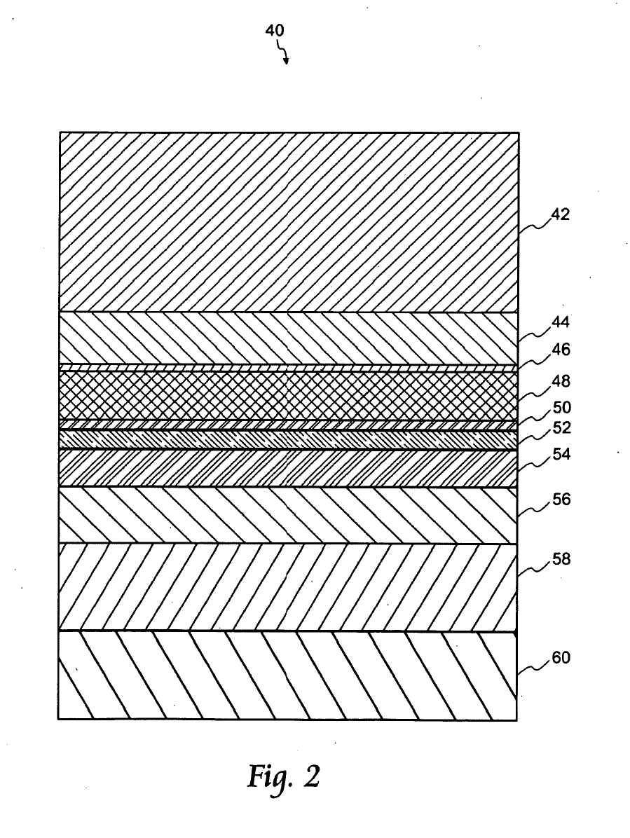

Referring now to FIG. 2, a solar panel 40 consistent with an embodiment of the present invention is illustrated. The panel 40 comprises a glass superstrate 42, a first layer of transparent conductive oxide (e.g., SnO₂, ZnO, InSnO, etc.) 44, a p-layer 46, an I-layer 48 and an n-layer 50 of amorphous silicon, a second layer of transparent conductive oxide 52 and then a back reflector layer 54 (comprising, for example, aluminum, silver or silver and titanium). It should be noted that the solar panel 40 is shown in position for use, with the glass superstrate 42 positioned to received sunlight there through. However, during fabrication, the glass superstrate 42 will generally be laid down first, with remaining layers being deposited thereon, and the completed panel will be inverted for use. It should further be noted that it would be possible to provide a solar panel having a glass substrate rather than a superstrate, with a transparent protective top coating, perhaps comprised of UV resistant plastic, positioned as the top most layer of the solar panel when in use.

As shown in FIG. 2, the solar panel 40 has a single junction of amorphous silicon, though it should be noted that instead of a single junction, it would be possible to use additional layers of amorphous or micro-crystalline silicon and/or additional layers of transparent conductive oxides to form additional junctions and create a multiple junction solar panel. In other embodiments of the present invention, other materials that convert sunlight to electricity could be used instead of amorphous or micro-crystalline silicon, including for example CdTe, CuInGaSe₂, nano-particles, or carbon nano-tubes, among others.

In this embodiment, an inorganic protective layer 56 (e.g., Si₃N₄ or SiO₂, silicon oxynitride or silicon carbide) is provided below the back reflector layer 54, and then a first thin-film polymer protective layer 58 and a second thin film polymer protective layer 60 are deposited thereon. The purpose of the inorganic protective layer 56 and the first and second polymer layers 58 and 60 is to protect the set of layers that form the solar cell. The inorganic protective layer 56 can be sputter deposited onto the back reflector layer 54 to create a very strong bond between it and the underlying layers of the solar panel 40. This layer protects the solar cells from water and pollutant degradation. The inorganic protective layer 56 can consist of one layer as described above or multiple inorganic layers (e.g., Si₃N₄, SiO₂, silicon oxynitride or silicon carbide) to improve or optimize polymer adhesion, abrasion resistance, corrosion resistance and microhardness.

Unlike the prior art, in which polymers are provided in sheet form and then laminated onto the back of the solar panel as described above, the polymers that will form the first and second polymer layers 58 and 60 are provided as monomers in liquid form, applied as a liquid onto the back of the solar panel 40 by, for example, spin-coating, roll-coating, or slot-coating, and then cured on the solar panel 40 by a suitable means, such as ultra-violet irradiation, heat, or chemical reaction between various components of the liquid. This process of curing the polymer on the solar panel creates a strong, tough conformal bond/coating. The conformal coating process displaces water and air from the panel surface, which the prior-art lamination process does not. This creates an inherently superior bond and interface. While the above example defines two conformal polymer layers 58 and 60 that are cured on the solar panel, multiple layers of polymers can be applied to optimize adhesion, wear, water and pollutant permeability, electrical conductivity and thermal expansion mismatches.

The process of lamination of thick sheets of polymer tends to create a weak adhesion between the polymer sheet and the back of the solar panel. In contrast, by careful choice of materials for the inorganic protective layer or layers and then the polymer layer or layers, the adhesion of a polymer layer that is cured in place to the inorganic layer can be significantly stronger. The polymer layers 58 and 60 can be formed from, by way of example, monomers of EVA, polyvinylfluoride, acrylates, or other polymer-forming monomers.

In the embodiment shown in FIG. 2, and in contrast to prior art solar panels utilizing laminated sheets of polymers as protective layers (as illustrated in FIG. 1), the adhesion of the inorganic and polymer protective layers 56, 58 and 60 is sufficiently strong that a frame is not required around the edges of the solar panel 40 to prevent the protective layers from peeling off the solar panel, beginning at the edges.

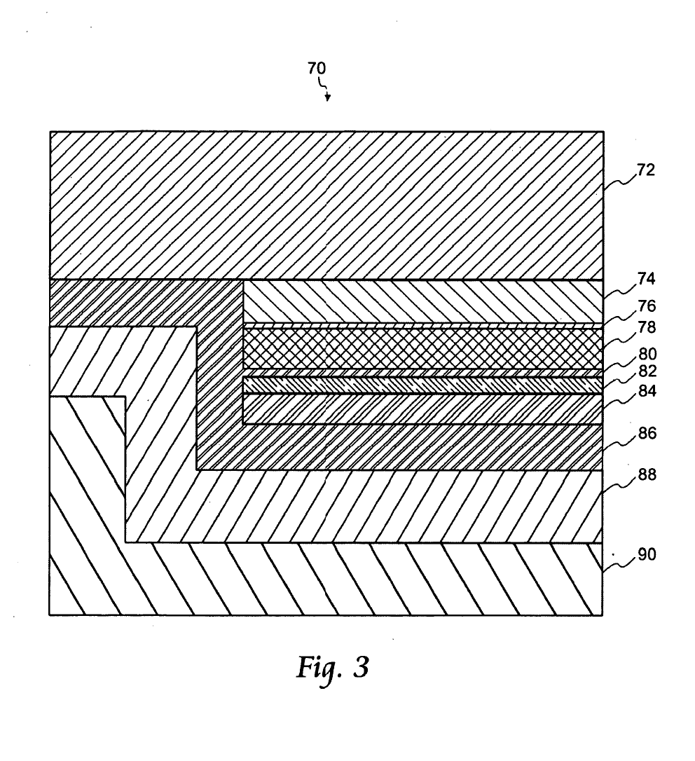

Referring now to FIG. 3, a solar panel 70 consistent with another embodiment of the present invention is shown. Like the solar panel 40 shown in FIG. 2, the solar panel 70 comprises a glass superstrate 72, a first layer of transparent conductive oxide 74, a p-layer 76, an I-layer 78 and an n-layer 80 of amorphous silicon, a second layer of transparent conductive oxide 82 and then a back reflector layer 84. In addition, and as shown in FIG. 2, an inorganic protective layer or layers 86 is/are provided below the back reflector layer 84, and then a first thin-film polymer protective layer 88 and a second thin film polymer protective layer 90 are deposited thereon. As in the previous example, multiple layers of polymer can be added to optimize the desired product life.

In the embodiment of FIG. 3, layers 74, 76, 78, 80, 82, and 84 are removed at the perimeter of the solar panel, exposing bare glass from glass superstrate 72 at the edge of solar panel on all four edges (only one edge is shown). The width of the exposure may be in the range of approximately one to 15 mm, with a range of from about three to about 10 mm being preferred in terms of achieving the goals of the present invention. The inorganic and polymer protective layers 56, 58 and 60 are deposited on top of the layers that form the solar panel and its conductors as described above with respect to the embodiment of FIG. 2. As shown in FIG. 3, the inorganic layer/layers 56 is/are deposited over the edges of layers 74, 76, 78, 80, 82, and 84, and onto the exposed edge of the glass superstrate 72, preferably extending out to the lateral edge of the glass superstrate 72 on all four edges. The polymer protective layers 58 and 60 are conformally coated, cured on the solar panel and bonded over the inorganic layer and, in one embodiment, extend over lateral edges of layers 78, 80, 82 and 84.

The inorganic layer or layers 56 is/are chosen so that it forms a strong bond to the glass superstrate 72. Since the glass superstrate 72 and the inorganic and polymer layers 86, 88 and 90 are chosen to be very resistant to degradation in outdoor environments, they effectively seal the solar panel 70 and its conductors 74 and 82 from the back and at the edges.

This seal is located away from the surface of the lateral edge of the glass superstrate 72, to prevent it from potential damage or other compromise of integrity by nicks or chips in the glass edge. As a result, a frame is not required to protect the edges of the protective layers 86, 88 and 90 from minor damage, such as chips or scratches.

The bus-bar (not shown) that collects electricity at the edges of a solar panel is a critical part of the solar panel that needs to be protected, both from corrosion and from detachment from the films that generate the electricity. In the prior art, the frame protects and promotes adhesion of the bus-bar. In one embodiment of this invention, the bus-bars are ribbons of metal that are welded to the back conductor of the solar cell with an ultrasonic welding system. Ultrasonic welding provides strong adhesion of the bus-bar to the solar panel without the need for a frame. In one embodiment of this invention, the bus-bar is welded to the back of the solar panel before the protective layers 86, 88 and 90 are applied. Thus, the bus-bar is protected by the same protective back coatings as the solar panel 70. Furthermore, the bus-bar metal can be chosen to be aluminum, titanium or another metal that itself is highly resistant to corrosion. Then, with the protective layers 86, 88 and 90 over the bus-bar metal, and with the bus-bar metal welded to the solar panel 70, the probability of corrosion is, relative to prior art designs, significantly lower even without a frame.

It is noted that solar panel glass is typically fabricated in very large sheets and then cut to size by first scribing the surface where a cut is desired and then encouraging the scratch created by the scribe to propagate into a cleave all the way through the thickness of the glass sheet, usually by stressing the sheet. If the glass has no internal defects such as bubbles, striae, or inclusions in the path of the cleave, the propagated part of the cleave is very smooth, and therefore very strong—in fact, smoother and stronger than most polishing operations produce. However, the region that was scratched by the scribe often has defects because scribing involves abrasion and highly localized pressure on the glass. In addition, glass is sensitive to chips and scratches at its edges, whether from rough handling or airborne debris. In the prior art, the frame protects the edges of the glass from airborne debris or rough handling that might chip an edge of the glass.

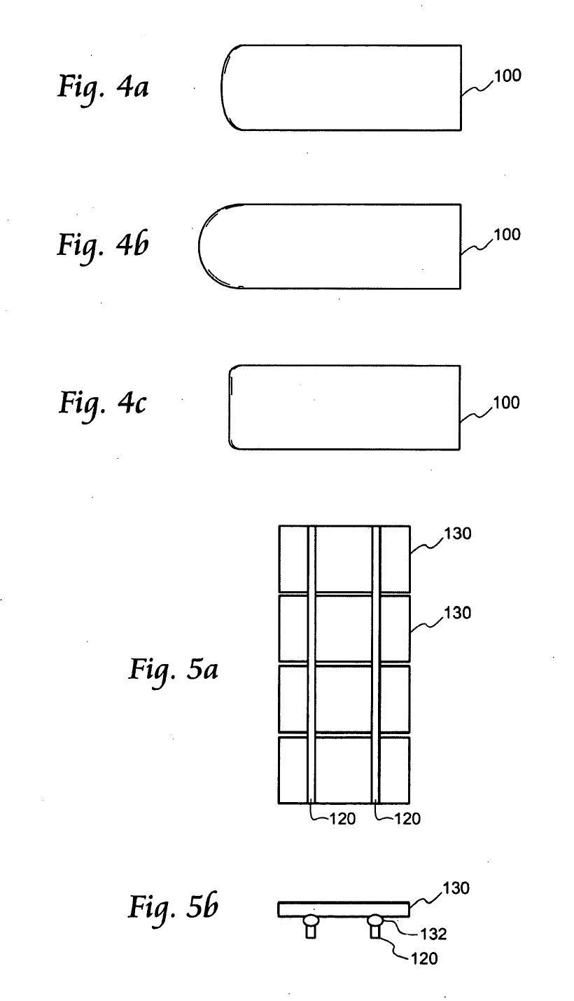

In a solar panel without a frame, as for example shown in FIGS. 2 and 3, the edges of the glass are exposed to the environment. To reduce the need for a frame to protect the glass, as shown in FIGS. 4(a)-(c), the edges of a glass substrate 100 may be ground, polished, or otherwise shaped (e.g., with laser shaping or diamond turning) with a contours. The contour may be, for example, elliptical, parabolic, oval, or catenary (FIG. 4(a)), semicircular (FIG. 4(b)), or with rounded corners (FIG. 4(c)). Since the defects and micro-cracks from the glass cutting process tend to be only near the surface that is cut, one can improve the strength and lifetime of the glass merely by grinding or polishing the part of the edge that is near the surface that was cut, as shown by way of example in FIG. 4(c), in which the middle section of the lateral edge of the glass superstrate 100 is left unpolished, thus saving manufacturing cost. However, for strength against airborne debris that might chip the lateral edge, it is preferable to have a contour along the entire lateral edge that is symmetrical from the top surface of the glass to the bottom surface of the glass, as shown by way of example in FIGS. 4(a)-(b). The contours illustrated in FIGS. 4(a)-(c) eliminate micro-cracks caused by the glass cutting process and give the lateral edge of the glass superstrate 100 great strength against airborne debris that might cause minor chips, scratches or other defects at the edges, eliminating the need for a frame to protect the edge of the glass solar panel.

In the field installation process for a prior art solar panel array, a supporting structure may be built consisting of horizontal beams supported by vertical posts. Then, the metal frames of the framed solar panels are attached to the horizontal beams with mounting brackets and mounting hardware, e.g., bolts. Referring now to FIGS. 5(a)-(b), for frameless solar panels as herein described, a different installation system and method are described. In this embodiment, a pair of supporting beams 120 is provided. An adhesive material 132 is then interposed between a top surface of the supporting beams 120 and an underside of the solar panels 130 that are to be mounted thereon. The choice of adhesive should provide strong adhesion, good compliance to withstand the stress created by differential thermal expansion between the glass solar panels and the material comprising the supporting beams 120 (e.g., metal), and a lifetime in outdoor environments for about 30 years or more. Silicone adhesives are one choice that meets these requirements, at least for typical panel-supporting structures of steel or aluminum.

An attachment of the solar panels to their supporting structure via an adhesive, as illustrated in FIGS. 5(a)-(b), offers several advantages over the prior art approach of bolting the frames of the solar panels to the supporting structure. A silicone adhesive, for example, is compliant, providing damping to the overall structure that minimizes vibration of the solar panels during times of high wind or percussive precipitation such as sleet, hail, or hard rain. Silicone adhesives are robust in outdoor environments for 30 or more years. By contrast, the metal bolts and nuts used in the prior art tend to corrode over time. The attachment of solar panels via adhesives may be readily automated, while the attaching of bolts and nuts is not readily automated. Automation of the attachment process can lower cost and improve quality. In addition, the preferred areas of adhesive attachment as shown in FIGS. 5(a) and (b) are on the back of the solar panel 130, rather than at the edges. The attachment points are preferably located relatively far from the edges of the solar panel to avoid collecting water or dirt that could encourage corrosion at the edges of the solar panel. Moreover, since the points of adhesive attachments are on the back of the solar panel they cannot shade the front of the solar panel in any way even if they do collect some dirt or debris.

In summary, in various embodiments of this invention, requirements normally met by a frame around the edges of the solar panel may be met without a frame. These include preventing de-lamination of the protective back layers, preventing damage to the protective back layers at the edges of the solar panel, promoting strong adhesion of the bus-bar, minimizing the risk of cracking the glass due to a scratch or chip at the edge of the solar panel, and providing a robust means for attaching the solar panels to an underlying metal supporting structure.

A frameless solar panel according to this invention is less expensive in materials cost, and requires less labor to assemble the complete structure, than prior-art framed solar panels. The assembly process can be automated as a continuous process that takes little factory space and minimizes the number of units scrapped in case of a process problem. Without the frame, the panel is lighter in weight; this weight reduction relaxes the load-bearing requirements on supporting structures and tracking mechanisms, reducing their cost as well. A frameless solar panel has a flat front surface all the way to its edges, rather than a frame that may shade part of the panel and reduce its output power and that may collect water or dirt at its edges.

Although particular embodiments of the invention have been described in detail for purposes of illustration, various modifications may be made without departing from the spirit and scope of the invention. Accordingly, the invention is not to be limited, except as by the appended claims.

We claim:

1. A solar panel comprising, in combination:
a transparent superstrate;
a first conductor disposed onto the superstrate;
wherein the first conductor forms a contact for the solar panel of a first polarity;
at least one device layer adapted to convert sunlight to electricity;
a second conductor;
wherein the second conductor forms a contact for the solar panel of a second, opposite polarity;
wherein the at least one device layer is interposed between the first and second conductors;
a reflector;
at least one protective layer located below the reflector;
wherein the at least one protective layer has been cured on the solar panel.

2. The solar panel of claim 1 further comprising at least two protective layers, comprising at least one inorganic layer and at least one polymer layer.

3. The solar panel of claim 2 wherein the inorganic layer comprises one of Si₃N₄ and SiO₂.

4. The solar panel of claim 2 wherein the polymer layer comprises one of EVA, polyvinyl fluoride and an acrylate.

5. The solar panel of claim 1 further comprising at least three protective layers, comprising at least one inorganic layer and at least two polymer layers.

6. The solar panel of claim 5 wherein the inorganic layer comprises one of Si₃N₄ and SiO₂ and wherein each of the two polymer layers comprises one of EVA, polyvinyl fluoride and an acrylate.

7. The solar panel of claim 1 wherein the at least one protective layer extends over a lateral edge of the first conductor, the second conductor, the semiconductor junction, and the reflector.

8. The solar panel of claim 1 wherein the at least one protective layer contacts an exposed edge region on an underside of the superstrate.

9. The solar panel of claim 1 wherein the exposed edge region has a width of between about 1 and about 15 millimeters.

10. The solar panel of claim 1 wherein the exposed edge region has a width of between about three and 10 millimeters.

11. The solar panel of claim 5 wherein the at least three protective layers extend over a lateral edge of the second conductor, the semiconductor junction, and the reflector.

12. The solar panel of claim 11 wherein one of the at least three protective layers contacts an exposed edge region on an underside of the superstrate.

13. The solar panel of claim 12 wherein the exposed edge region has a width of between about 1 and about 15 millimeters.

14. The solar panel of claim 13 wherein the exposed edge region has a width of between about three and 10 millimeters.

15. The solar panel of claim 1 further comprising a support structure positioned below the at least one protective layer and an adhesive interposed between the support structure and the at least one protective layer.

16. The solar panel of claim 15 wherein the adhesive is silicone.

17. The solar panel of claim 16 wherein the support structure comprises at least one horizontal beam.

18. The solar panel of claim 1 wherein a lateral edge of the superstrate is contoured.

19. The solar panel of claim 18 wherein the contoured lateral edge of the superstrate is one of semicircular, elliptical, catenary, oval, and parabolic.

20. The solar panel of claim 1 wherein adhesion of the at least one protective layer is sufficiently strong that a frame is not required around edges of the solar panel to prevent the at least one protective layer from peeling off the solar panel, beginning at the edge, during use.

21. A method for fabricating a solar panel comprising:
providing a transparent superstrate;
disposing a first conductor onto the superstrate;
wherein the first conductor forms a contact for the solar panel of a first polarity;
providing at least one device layer adapted to convert sunlight to electricity;
providing a second conductor;
wherein the second conductor forms a contact for the solar panel of a second, opposite polarity;
wherein the at least one device layer is interposed between the first and second conductors;
providing a reflector;
curing at least one protective layer on to the solar panel below the reflector.

22. The method of claim 21 further comprising one of sputter depositing, spin-coating, roll-coating, slot-coating, and spray coating and then curing at least two protective layers onto the solar panel below the reflector.

23. The method of claim 22 wherein the inorganic layer comprises one of Si₃N₄ and SiO₂.

24. The method of claim 22 wherein the polymer layer comprises one of EVA, polyvinyl fluoride, and an acrylate.

25. The method of claim 21 further comprising depositing at least three protective layers onto the solar panel below the reflector, wherein the at least three protective layers comprise at least one inorganic layer and at least two polymer layers that are cured on the solar panel.

26. The method of claim 25 wherein the inorganic layer comprises Si₃N₄ and SiO₂and wherein each of the two polymer layers comprises one of EVA, polyvinyl fluoride and an acrylate.

27. The method of claim 21 wherein the at least one protective layer is one of sputter-deposited, spin-coated, roll-coated, slot-coated and spray coated and then cured to extend over a lateral edge of the first conductor, the second conductor, the semiconductor junction, and the reflector.

28. The method of claim 21 wherein the at least one protective layer is one of sputter-deposited, spin-coated, roll-coated, slot-coated, and spray coated and then cured to contact an exposed edge region on an underside of the superstrate.

29. The method of claim 21 wherein the exposed edge region has a width of between about 1 and about 15 millimeters.

30. The method of claim 21 wherein the exposed edge region has a width of between about three and 10 millimeters.

31. The method of claim 25 wherein the at least three protective layers are one of sputter-deposited, spin-coated, roll-coated, slot-coated, and spray coated and then cured to extend over a lateral edge of the second conductor, the semiconductor junction, and the reflector.

32. The method of claim 31 wherein one of the at least three protective layers are one of sputter-deposited, spin-coated, roll-coated, slot-coated, and spray coated and then cured to contact an exposed edge region on an underside of the superstrate.

33. The method of claim 32 wherein the exposed edge region has a width of between about 1 and about 15 millimeters.

34. The method of claim 33 wherein the exposed edge region has a width of between about three and 10 millimeters.

35. The method of claim 21 comprising positioning the solar panel on a support structure and interposing an adhesive between the solar panel and the support structure.

36. The method of claim 35 wherein the adhesive is silicone.

37. The solar panel of claim 21 further comprising contouring a lateral edge of the superstrate.

38. The solar panel of claim 37 wherein the contoured lateral edge of the superstrate is one of semicircular, elliptical, oval, catenary, and parabolic.

39. The solar panel of claim 21 further comprising welding a bus bar directly to the bottom-most conductor layer prior to the step of one of sputter-depositing, spin-coating, roll-coating, slot-coating, and spray coating and then curing at least one protective layer onto the solar panel below the reflector, so that at least one protective layer protects said bus bar from outside exposure.

40. The solar panel of claim 21 wherein adhesion of the at least one protective layer is sufficiently strong that a frame is not required around edges of the solar panel to prevent the at least one protective layer from peeling off the solar panel, beginning at the edge, during use.

41. A solar panel comprising, in combination:
a transparent superstrate;
a first conductor disposed onto the superstrate;
wherein the first conductor forms a contact for the solar panel of a first polarity;
at least one device layer adapted to convert sunlight to electricity;
a second conductor;
wherein the second conductor forms a contact for the solar panel of a second, opposite polarity;
wherein the at least one device layer is interposed between the first and second conductors;
a reflector;
at least three protective layers located below the reflector, comprising at least one inorganic layer and at least two polymer layers;
wherein the at least three protective layers have been cured on the solar panel;
wherein the at least one inorganic layer comprises one of Si₃N₄ and SiO₂;
wherein each of the at least two polymer layers comprises one of EVA, polyvinyl fluoride and an acrylate;
wherein the at least three protective layers extend over a lateral edge of the first conductor, the second conductor, the semiconductor junction, and the reflector; and
wherein adhesion of the at least three protective layers is sufficiently strong that a frame is not required around edges of the solar panel to prevent the at least three protective layers from peeling off the solar panel, beginning at the edge, during use.

42. A method for converting sunlight into electricity, comprising:
providing a photovoltaic cell comprising, in combination:
a transparent superstrate;
a first conductor disposed onto the superstrate;
wherein the first conductor forms a contact for the solar panel of a first polarity;
at least one device layer adapted to convert sunlight to electricity;
a second conductor;
wherein the second conductor forms a contact for the solar panel of a second, opposite polarity;
wherein the at least one device layer is interposed between the first and second conductors;
a reflector;
at least one protective layer located below the reflector;
wherein the at least one protective layer has been cured on the solar panel;
positioning the photovoltaic cell so that sunlight may enter the glass superstrate and thereafter pass through the device layer, where a portion of the sunlight is converted into electricity; and
outputting the electricity from the photovoltaic cell.

40. The method of claim 39 wherein adhesion of the at least one protective layer is sufficiently strong that a frame is not required around edges of the solar panel to prevent the at least one protective layer from peeling off the solar panel, beginning at the edge, during use.
